(19) United States
(12) Patent Application Publication
(10) Pub. No.: US 2010/0297347 A1
(43) Pub. Date: Nov. 25, 2010

(54) SUBSTRATE SUPPORT HAVING SIDE GAS OUTLETS AND METHODS

(75) Inventors: Manoj Vellaikal, Sunnyvale, CA (US); Majeed Foad, Sunnyvale, CA (US); Jose Antonio Marin, San Jose, CA (US); Scott D. McClelland, San Jose, CA (US)

Correspondence Address: Ashok K. Janah, 650 DELANCEY STREET, SUITE 106, SAN FRANCISCO, CA, 94107, US

(73) Assignee: Applied Materials, Inc., Santa Clara, CA (US)

(21) Appl. No.: 12/766,845

(22) Filed: Apr. 23, 2010

Related U.S. Application Data
(60) Provisional application No. 61/214,514, filed on Apr. 24, 2009.

(51) Int. Cl. C23C 16/455

(52) U.S. Cl. 427/248.1; 118/728

(57) ABSTRACT

A substrate support for a process chamber comprises an electrostatic chuck having a receiving surface to receive the substrate and a gas distributor baseplate below the electrostatic chuck. The gas distributor baseplate comprises a circumferential sidewall having a plurality of gas outlets that are spaced apart from one another to introduce a process gas into the process chamber from around the perimeter of the substrate and in a radially outward facing direction.

### RELATED APPLICATION

Under 35 U.S.C. §119(e), the present application claims the benefit of the filing date of Provisional Application No. 61/214,514, filed on Apr. 24, 2009, titled: “SUBSTRATE SUPPORT HAVING SIDE GAS OUTLETS AND METHODS”, which is incorporated by reference herein in its entirety.

### BACKGROUND

Embodiments of the present invention relate to a substrate support for a deposition and ion implantation apparatus and related methods.

In the fabrication of electronic circuits, solar panels, and other microelectronic devices, various layers and features are formed on a substrate, such as a semiconductor wafer or glass panel. For example, layers of dielectric and semiconducting and conducting materials can be deposited on the substrate. Some of the layers are subsequently processed to form features such as interconnect lines, contact holes, gates and others. Semiconducting layers of material such as polysilicon can also be deposited on the substrate. The semiconductor layers are subsequently implanted with ions to form n-doped or p-doped regions. For example, polysilicon can be deposited in a deposition chamber. Thereafter, an ion implantation process is performed in a separate ion implantation chamber to form gate and source drain structures with desired profile and concentration of ions. In such processing, the substrate has to be transported from one chamber to the other in a cassette or by a robotic arm. During such transportation, the substrate can be contaminated by particles from the cassette, robotic arm, or even the clean room environment.

Single chambers that are capable of both tasks of depositing semiconducting or other materials and implanting ions in the deposited layers have been developed. In these processes, a semiconducting layer is deposited on the substrate, and an ion implantation process is used to implant and dope ions into the deposited layer or underlying substrate. During the deposition and ion implantation processes, different process gases or gas mixtures may be used to provide the deposition material or source species. For example, such chambers and various processes are described in commonly assigned U.S. Patent Publication No. 2008/0138967A1, published Jun. 12, 2008, entitled PLASMA IMMERSED ION IMPLANTATION PROCESS by Le et al.; U.S. Patent Publication No. 2004/0166612 A1, published Aug. 26, 2004, entitled FABRICATION OF SILICON-ON-INSULATOR STRUCTURE USING PLASMA IMMERSION ION IMPLANTATION by Dan Maydan et al.; U.S. Patent Publication No. 2004/0107909 A1, published Jun. 10, 2004, entitled PLASMA IMMERSION ION

IMPLANTATION PROCESS USING A PLASMA SOURCE HAVING LOW DISSOCIATION AND LOW MINIMUM PLASMA VOLTAGE by Kenneth Collins et al.; and U.S. Patent Publication No. 2003/0226641 A1, published Dec. 11, 2003, entitled EXTERNALLY EXCITED TORROIDAL PLASMA SOURCE WITH MAGNETIC CONTROL OF ION DISTRIBUTION by Kenneth Collins et al.; all of the above are incorporated by reference herein and in their entireties.

However, while conventional deposition and implantation chambers provide good results for the deposition and ion implantation of a variety of different materials, they do not always provide a uniformly deposited film for certain materials or do not fulfill particularly tight feature tolerances. It is often difficult to deposit and implant ions in semiconducting films such as polysilicon with a uniform thickness using conventional deposition and ionization chambers. For example, chambers which have gas delivery ports located on the bottom wall of the chamber on which the substrate support is mounted have been found to deposit imperfect and non-uniform semiconducting layers. Even slightly non-uniform thicknesses or varying ion concentrations in the deposited material are unacceptable due to ever increasing demands of micro-electronic devices associated with ultra large scale integration (ULSI) which require increased transistor and circuit speed, density, and improved reliability. In particular, these demands require formation of features with high precision and uniformity.

Thus, there is a need for improved apparatus, systems, and methods for depositing and/or implanting material onto a substrate. These and other problems are addressed by the apparatus and methods of the present invention.

### SUMMARY

A substrate support for a process chamber comprises an electrostatic chuck having a receiving surface to receive the substrate and a gas distributor baseplate below the electrostatic chuck. The gas distributor baseplate comprises a circumferential sidewall having a plurality of gas outlets that are spaced apart from one another to introduce a process gas into the process chamber from around the perimeter of the substrate and in a radially outward facing direction.

A method of depositing a material on a substrate comprising holding the substrate in the chamber and flowing process gas into the chamber from spaced apart points that are abutting, and outside, the perimeter of the substrate and in a radially outward facing direction. The process gas is energized to deposit material onto the substrate.

A process chamber is capable of depositing material and implanting ions in a substrate. The process chamber comprises a housing having enclosure walls and a substrate support for receiving a substrate in the housing. The substrate support comprises an electrostatic chuck having a receiving surface to receive the substrate and a gas distributor baseplate below the electrostatic chuck. The gas distributor baseplate comprises a circumferential sidewall having a plurality of gas outlets that are spaced apart from one another to introduce a process gas into the housing from around the perimeter of the substrate and in a radially outward facing direction. A plasma-generating system energizes the process gas to form a plasma capable of depositing material on the substrate or implanting ions into the substrate. An exhaust is provided to exhaust the process gas from the process chamber.

### DRAWINGS

These features, aspects, and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 is a schematic cross-sectional view of an embodiment of a substrate support comprising an electrostatic chuck and a gas distributor baseplate;

FIG. 2 is a perspective view of an embodiment of a substrate support comprising an electrostatic chuck and a gas distributor baseplate;

FIG. 3A is a schematic perspective view of an embodiment of a gas distributor baseplate comprising a circumferential sidewall having an array of gas outlets that flow gas into the chamber in a radially outward direction relative to the substrate;

FIG. 3B is a top plan view of the gas distributor baseplate of FIG. 3A showing an embedded annular feed channel that supplies process gas to the gas outlets;

FIG. 4 is a schematic partial sectional side view of an embodiment of a process chamber capable of depositing and implanting ions onto a substrate; and

FIG. 5 is a schematic partial sectional perspective view of the process chamber of FIG. 4.

### DESCRIPTION

An embodiment of a deposition and ion implantation system according to the present invention is capable of depositing a layer on a substrate 24 and implanting ions into the substrate 24 by a plasma immersion ion implantation process. In one embodiment, a deposition process can be performed by supplying a process gas comprising a deposition gas into the process chamber 60 and forming a plasma of the deposition gas to deposit a layer on the substrate 24. An ion implantation process can then be performed in the same chamber 60 by supplying a different process gas comprising ion precursor gases into the process chamber 60 and generating a plasma of these process gas to dissociate ions from the gas. The dissociated ions are accelerated toward and implanted into the substrate by applying a bias voltage across a travelling path of the ions.

The substrate 24 comprises a semiconductor material, such as silicon, polycrystalline silicon, germanium, silicon germanium, or a compound semiconductor. A silicon wafer can have single or large crystals of silicon. An exemplary compound semiconductor comprises gallium arsenide. The substrate 24 can be made from the semiconductor material (as shown) or can have a layer of semiconductor material thereon (not shown). For example, a substrate 24 comprising a dielectric material, such as a panel or display, can have a layer of semiconductor material deposited thereon to serve as the active semiconducting layer of the substrate. Suitable dielectric materials include borophosphosilicate glass, phosphosilicate glass, borosilicate glass and phosphosilicate glass.

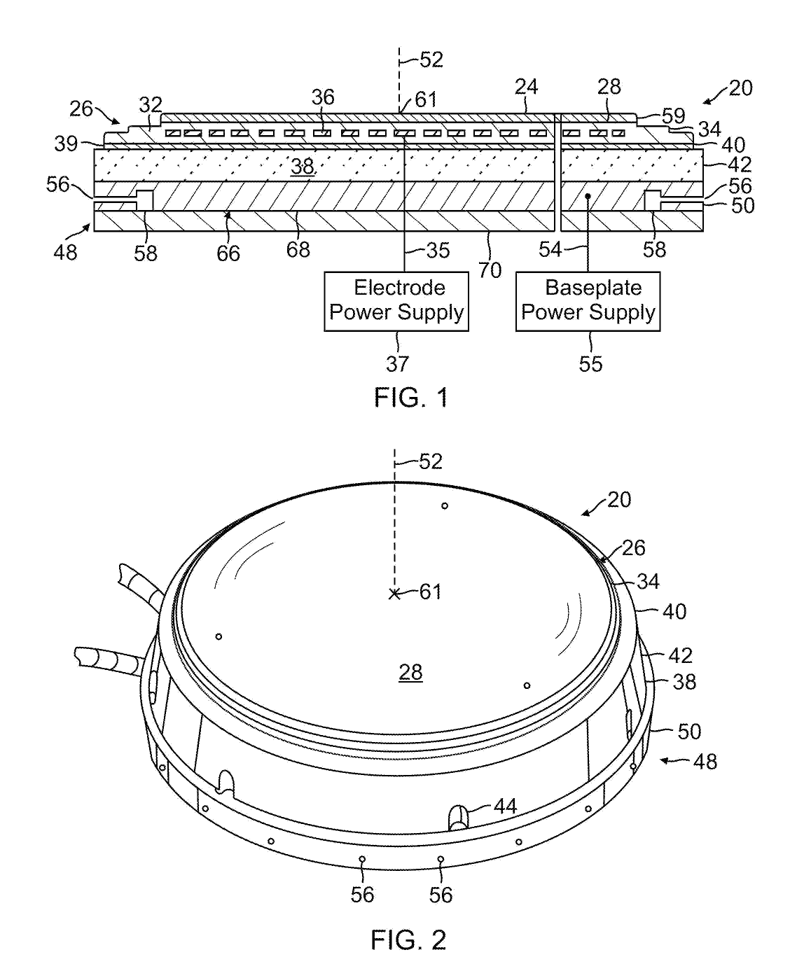

An embodiment of a substrate support 20 that is used to receive a substrate 24 in a process chamber 60 is shown in FIG. 1. The substrate support 20 comprises an electrostatic chuck 26 comprising a receiving surface 28 that is a disc-like shape that matches the shape and size of the substrate 24 held on the electrostatic chuck 26. The electrostatic chuck 26 comprises dielectric puck 32 having an embedded electrode 36. The dielectric puck 32 desirably comprises a material permeable to electromagnetic energy, e.g., at least one of aluminum nitride, aluminum oxide, and titanium oxide, and preferably comprises aluminum nitride. The dielectric puck 32 can, however, also comprise other materials such as polymer (for example, polyimide). The dielectric puck 32 has a thickness of from about 5 to about 15 mm, e.g., about 10 mm. The dielectric puck 32 can also have an outwardly extending stepped annular flange 34. A metal plate 39 can also be bonded to the bottom of the dielectric puck 32 to facilitate handling and to allow fastening the electrostatic chuck 26 to the underlying structures. The metal plate 39 can, for example, be made of an aluminum alloy such as aluminum and silicon, and in one version, comprises porous silicon carbide infiltrated with aluminum.

The electrode 36 of the electrostatic chuck 26 is chargeable and can be a monopolar electrode or a bipolar electrode. Typically, the electrode 36 is composed of a metal. In operation, the electrode 36 can be provided with a terminal 35 that is connected to an electrode power supply 37 to receive a voltage, which may be an AC or DC voltage to charge the electrode 36 to electrostatically hold the substrate 24. The electrode power supply 37 can also provide the electrode 36 with an RF power to provide RF excitation for the process chamber. In one exemplary embodiment, the electrode 36 comprises a molybdenum wire mesh.

The substrate support 20 further includes a dielectric pedestal 38 below the electrostatic chuck 26. In the version shown, the dielectric pedestal 38 comprises a cylinder having a flange 40 that extends outside the perimeter of the electrostatic chuck 26, and a sloped sidewall 42. As shown for example in FIG. 2, the sidewall 42 maybe sloped at an angle of from about 5 to about 15°. Recessed holes 44 are spaced apart about the sloped sidewall 42 to serve as access points for fastening mechanisms such as screws and bolts. The dielectric pedestal 38 comprises a dielectric material to electrically isolate the electrostatic chuck 26 from support structures and/or the lower chamber wall. In one version, the dielectric pedestal 38 comprises a polymer such as a polycarbonate. In one embodiment, the dielectric pedestal comprises Lexan (TM, SABIC Innovative Plastics), which has suitable strength and impact resistance properties.

A gas distributor baseplate 48 below the electrostatic chuck 26 comprises a circumferential sidewall 50. The baseplate 48 comprises a disk-shaped structure having a central axis 52 that is an axis of rotational symmetry. For example, the gas distributor baseplate 48 can be in the shape of a right cylinder. The gas distributor baseplate 48 can be made from a conductor to serve as an electrode for the process chamber 60. For example, the gas distributor baseplate 48 can serve as a cathode. Suitable metals include stainless steel and aluminum. The gas distributor baseplate 48 also has an electrical connector 54 to connect to a baseplate power supply 55 to maintain the baseplate 48 at an electrical potential (which may be a voltage, floating potential, or ground) relative to the enclosure walls of the process chamber 60.

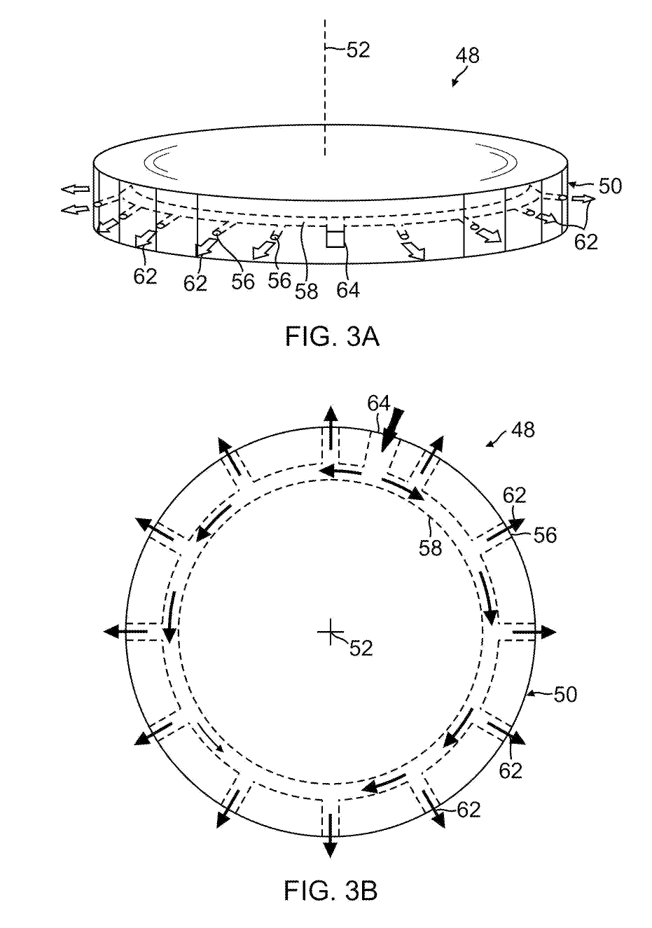

The gas distributor baseplate 48 comprises a plurality of gas outlets 56 that are spaced apart from one another to introduce process gas into the process chamber 60 from around the perimeter 59 of the substrate 24. The gas outlets 56 are located below the plane of the substrate 24 and terminate about, or immediately beyond a radial distance corresponding to the radius of the substrate 24. In one version, the gas outlets 56 terminate at a distance that is beyond the radial distance from the center 61 of the substrate to the perimeter 59 of the substrate 24, and are located at a level which is below the level of the plane of the substrate 24. The gas outlets 56 are oriented to release a flow pattern of gas from around the perimeter 59 of the substrate 24 and in a radially outward facing direction, as shown schematically by the arrows in FIG. 3A. The gas outlets 56 can be spaced apart around the circumferential sidewall 50 of the baseplate 48 as measured from the central axis of symmetry 52 by an angle of from about 5° to about 45°. This allows the process gas to be introduced from points that are radially spaced apart around the perimeter 59 of the substrate 24 and below the substrate 24. The gas distributor baseplate 48 can comprise a plurality of gas outlets 56, such as from about 4 to about 100 gas outlets 56, or even from about 10 to about 20 gas outlets 56. In the embodiment shown schematically in FIG. 3B, the gas distributor baseplate 48 comprises twelve of the gas outlets 56.

Distribution of the process gas about the perimeter of the substrate 24 and from a lower level enables the process gas to be more uniformly distributed to the substrate 24. Without being limited by explanation, it is believed that better deposition uniformity results because the process gas is emitted into the housing of the process chamber 60 from around the entire perimeter 59 of the substrate 24 and maintained at a temperature approximating that of the substrate processing temperature. The gas distributor baseplate 48, being made of metal, equilibrates within a short time to the temperature of the process chamber 60 and reaches a few degrees above or below that of the substrate 24. As the gas passes through the baseplate 48, it is heated (or cooled) to approximately the same temperature as the substrate 24. Emitting gas about the substrate perimeter 59 and maintaining the emitted gas at about the same temperature as the substrate 24, or slightly lower, enhances reaction rates across the substrate 24 and provides more uniform deposition of material.

Further, because the process gas flow 62 is directed in a radially outward direction facing away from the substrate surface, the process gas can dissipate into the chamber 60 without gas streams forming streaks across the substrate surface. Still further, directing the gas away from the substrate 24 pushes away residue particles which flake off from chamber walls and component surfaces and prevent these flaked-off particles from falling onto and contaminating the substrate surface. Also, fewer particles are elevated and floated across the substrate surface because the gas flow 62 is directed in a horizontally oriented direction and not in a vertically oriented direction as in conventional showerhead distributors or gas holes that are in the lower wall of the chamber 60 and which are vertically oriented.

The gas outlets 56 of the gas distributor baseplate 48 have a shape and size that are selected to enable sufficiently high flow rate of process gas therethrough. However, the gas outlets 56 should also be sized with a diameter that is sufficiently small to reduce or even prevent back-flow of process gas into the outlets 56 and prevent plasma discharges or arcing within the interior space of the gas outlets 56. A suitable size for the gas outlets 56 comprises a diameter of from about 1 mm to about 10 mm. In one exemplary embodiment, the gas outlets 56 are sized with a diameter of from about 1.2 to about 1.4 mm, or even about 1.25 mm.

The gas distributor baseplate 48 comprises an annular feed channel 58 to provide process gas to the gas outlets 56. The annular feed channel 58 can comprise a gas connector 64 to receive process gas and provide the gas to the annular feed channel 58. For example, the gas connector 64 can be capable of connecting to a gas feed port (not shown) in the process chamber 60. The annular feed channel 58 can be formed in the gas distributor baseplate 48 by machining an annular groove into the bottom side 66 of a gas distributor baseplate preform 68, as shown for example in FIG. 1. The annular groove can then be sealed off by seam-welding a lower plate 70 over the baseplate preform 68 to form a gas distributor baseplate 48 with an annular feed channel 58. The annular feed channel 58 has a cross-sectional area that is sufficient to provide process gas to each of the gas outlets 56 with a substantially uniform pressure. In one embodiment, the annular feed channel 58 comprises a rectangular cross-section with a width of from about 2 to about 20 mm or even about 6 mm, and a depth of from about 5 to about 25 mm or even about 13 mm.

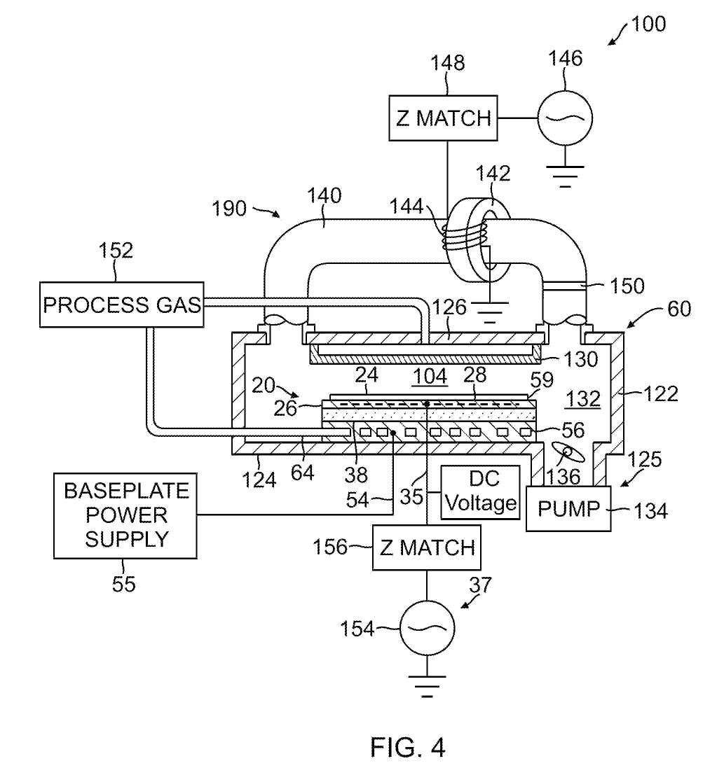

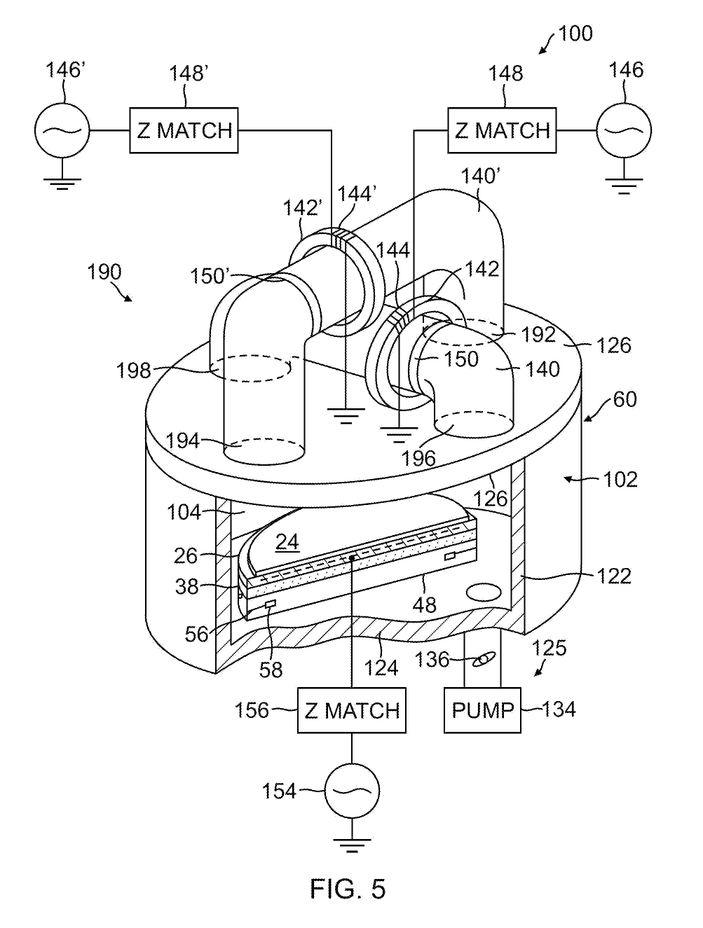

The substrate support 20 can be used to hold a substrate 24 in a process chamber 60 of a substrate processing apparatus 100. The substrate processing apparatus 100 can both deposit material onto the substrate 24 as well as ionize a plasma and form ions which are implanted into the substrate 24. The ions can be implanted into the substrate 24 before or during a deposition process. FIGS. 4 and 5 show an apparatus 100 that may be utilized to practice ion implantation and to form layers on the substrate 24. For example, the process chamber 60 can be used to deposit polysilicon layers on the substrate 24. One suitable process chamber 60 which may be adapted to practice the invention is a P3i™ reactor (available from Applied Materials, Inc., of Santa Clara, Calif.). However, other chambers and processes can also utilize the substrate support 20 with gas distributor baseplate 48, and the scope of the present claims should not be limited to the exemplary embodiments of chambers, apparatus, and other components described herein. In the P3i chamber, a spinning torroidal field regenerates the plasma of the oxygen-containing gas in the chamber. These oxygen ions are typically implanted with an ion implantation energy of from about 50 eV to about 500 eV. In yet other versions, an accelerated plasma such as a radio frequency (RF) or direct current (DC) bias can be applied to electrodes about the process zone to generate the plasma.

The process chamber 60 includes a chamber body 102 having a bottom 124, a top 126, and sidewalls 122 enclosing a process region 104. A substrate support assembly is supported from the bottom 124 of the chamber body 102 and is adapted to receive a substrate 24 for processing. The substrate support 20 can also include other components such as movable pedestal, lift pin assembly, one or more gas feedthroughs, and electrical connectors (not shown). A gas distribution plate 130 can optionally be coupled to the top 126 of the chamber body 102 facing the substrate support 20. A process gas source 152 is coupled to the gas distribution plate 130 to supply gaseous precursor compounds for processes performed on the substrate 24. An exhaust 125 of the process chamber 60 includes a pumping port 132 in the chamber body 102 which is coupled to a vacuum pump 134. The vacuum pump 134 is coupled through a throttle valve 136 to the pumping port 132.

The process chamber 60 further includes a plasma-generating system 190 to energize the process gas to form a plasma capable of depositing material on the substrate 24 or implanting ions into the substrate 24. The plasma generating system 190 includes a pair of separate external reentrant conduits 140, 140′ mounted on the outside of the top 126 of the chamber body 102. The first and second conduits 140, 140′ are coupled to openings 198, 196 and 192, 194, respectively. An orthogonal configuration of the external reentrant conduits 140, 140′ allows plasma to be distributed uniformly across the process region 104. Magnetically permeable torroidal cores 142, 142′ surround a section of corresponding reentrant conduits 140, 140′. A pair of conductive coils 144, 144′ are coupled to respective RF plasma source power generators 146, 146′ through respective impedance match circuits or elements 148, 148′. Each external reentrant conduit 140, 140′ is a hollow conductive tube interrupted by a pair of insulating annular rings 150, 150′, respectively, that interrupt an otherwise continuous electrical path between the two ends of the respective external reentrant conduits 140, 140′.

The plasma-generating system 190 further includes an RF plasma bias power generator 154 coupled to the substrate support 20 through an impedance match circuit or element 156 to control the energy at ions being implanted into the substrate surface. For example, RF power can be coupled to the electrode 36 of the electrostatic chuck 26 or to the gas distributor baseplate 48 which can also act as an electrode in the chamber 60 or can be coupled to both the embedded electrode 36 and the gas distributor baseplate 48.

Referring back to FIG. 4, process gases, including gaseous compounds supplied from the process gas source 152, are introduced into the process region 104. Process gases can be introduced into process region 104 through the gas distributor baseplate 48 through an overhead gas distribution plate 130 or through both the baseplate 48 and an overhead gas distribution plate 130. The process gas source 152 can provide different process gases that may be utilized to process the substrate 24—for example, to deposit a layer on the substrate 24 or to implant ions into the substrate 24 by a plasma immersion ion implantation process. The process gas source 152 can be used to provide process gas to the gas distributor baseplate 48 and the overhead gas distribution plate 130 that is the same or different gas composition. For example, a first gas composition can be provided to the gas distributor baseplate 48, and a second process gas composition can be provided to the overhead gas distribution plate 130. Further, the process gas source 152 can provide flow rates of process gas to the gas distributor baseplate 48 and the overhead gas distribution plate 130 that are the same or different flow rates. For example, a first flow rate of process gas can be provided to the gas distributor baseplate 48 and a second flow rate of process gas can be provided to the overhead gas distribution plate 130.

A process gas for the deposition of silicon or polysilicon can include deposition gases such as a silane-based gas and H₂ gas. Suitable examples of the silane-based gas include, but are not limited to, mono-silane (SiH₄), di-silane(Si₂H₆), silicon tetrafluoride (SiF₄), silicon tetrachloride(SiCl₄), and dichlorsilane (SiH₂Cl₂), and the like. The gas ratio of the silane-based gas and H₂ gas is maintained to control reaction behavior of the gas mixture, thereby allowing a desired proportion of the crystallization in the deposited polysilicon film.

In one embodiment, the silane-based gas is SiH₄, which may be supplied at a flow rate of at least about 0.2 slm/m², and the H₂ gas, which may be supplied at a flow rate of at least about 10 slm/m². Alternatively, the gas mixture of SiH₄ gas and H₂ gas may be supplied at a volumetric flow ratio of SiH₄ to H₂ of from about 1:20 to about 1:200, and at a process pressure of from about 1 Torr to about 100 Torr, (e.g., about 3 Torr to about 20 Torr).

The deposition gas can also include one or more inert gases, such as (but not limited to) noble gas, e.g., argon, helium, xenon and the like. The inert gas may be supplied at a flow ratio of inert gas to H₂ gas of between about 1:10 and about 2:1.

In one embodiment, a silicon dioxide layer may be deposited over an ion-implanted film by flowing silane gas at 15 sccm, oxygen gas at about 50 sccm to about 60 sccm, argon gas at about 300 sccm, and applying an RF bias of about 200 watts. The deposition occurs for about 1 minute to about 2 minutes and deposits a silicon dioxide capping layer of about 50 angstroms to about 60 angstroms thickness.

Suitable examples of ion implantation process gases include B₂H₆, BF₃, SiH₄, SiF₄, PH₃, P₂H₅, PO₃, PF₃, PF₅ and CF₄, among others. The ions implanted depend upon the type of semiconductor material of the substrate 24 or semiconducting layer deposited on the substrate 24. For example, the source and drain regions of a substrate 24 comprising a silicon wafer can have implanted n-type and p-type dopants. Suitable n-type dopant ions, when implanted in silicon, include, for example, at least one of phosphorous, arsenic, and antimony. Suitable p-type dopant ions include, for example, at least one of boron, aluminum, gallium, indium, and thallium. For example, a source region can be formed by implanting a p-type dopant (such as boron) into a semiconductor material comprising silicon, and the drain region can be formed by implanting an n-type dopant (such as arsenic or phosphorous) into the semiconductor material. The source and drain regions form a p-n junction at the boundary between the two regions. In one example, these ions are implanted into the semiconductor material in a dosage level of from about 1×10¹⁴ atoms/cm² to about 1×10¹⁷ atoms/cm².

The ion-implanted layer can be exposed to other process gases to deposit a layer onto the ion-implanted layer of the substrate 24. For example, the implanted layer may be exposed to an oxygen-containing gas to deposit an oxide layer, or to gases comprising silicon, oxygen, nitrogen, carbon, and combinations thereof. Suitable gases that may be introduced to the chamber 60 include silicon-containing gases, oxygen-containing gases, nitrogen-containing gases, and carbon-containing gases. Examples of suitable nitrogen gases include ammonia, hydrazine, organic amines, organic hydrazines, organic diazines, silylazides, silylhydrazines, hydrogen azide, hydrogen cyanide, atomic nitrogen, nitrogen, phenylhydrazine, azotertbutane, ethylazide, derivatives thereof, or combinations thereof. Carbon sources include organosilanes, alkyls, alkenes and alkynes of ethyl, propyl, and butyl. Such carbon sources include methylsilane, dimethylsilane, ethylsilane, methane, ethylene, ethyne, propane, propene, butyne, as well as others. Layer formation gases may be provided to the chamber 60 with a carrier gas. In one embodiment, argon is used as the carrier gas and may be provided at a flow rate of about 300 sccm. RF power may be supplied at about 200 watts to about 2000 watts during CVD.

The process gases can be energized to form a plasma in the process chamber 60 by the RF plasma source power generators 146, 146′ can be coupled from the power applicator to gases supplied in conduits 140, 140′ to create circulating plasma currents, closed torroidal paths through conduits 140, 140′ and the process region 104. The plasma currents of the conduits 140, 140′ can be made to oscillate (e.g., reverse direction) at the frequencies of the respective RF plasma source power generators 146, 146′, which may be the same or slightly offset from one another.

In plasma immersion ion implantation, plasma source power generators 146, 146′ are operated to dissociate the process gases supplied from the process gas source 152 and produce a desired ion flux at the surface of the substrate 24. The power of the RF plasma bias power generator 154 is controlled at a selected level at which the ion energy dissociated from the process gases may be accelerated toward the surface of the substrate 24 and implanted at a desired depth below the top surface of the substrate 24 with desired ion concentration. A combination of the controlled RF plasma source power and RF plasma bias power dissociates ions in the gas mixture having sufficient momentum and desired ion distribution in the process chamber 60. The ions are biased and driven toward the substrate surface, thereby implanting ions into the substrate 24 with desired ion concentration, distribution, and depth from the surface of the substrate 24. Furthermore, the controlled ion energy and different types of ion species from the supplied process gases facilitates ions implanted in the substrate 24, forming desired device structure such as gate structure and source/drain regions on the substrate 24.

Although exemplary embodiments of the present invention are shown and described, those of ordinary skill in the art may devise other embodiments which incorporate the present invention and which are also within the scope of the present invention. Furthermore, the terms below, above, bottom, top, up, down, first and second and other relative or positional terms are shown with respect to the exemplary embodiments in the figures and are interchangeable. Therefore, the appended claims should not be limited to the descriptions of the preferred versions, materials, or spatial arrangements described herein to illustrate the invention.

What is claimed is:

1. A substrate support for receiving a substrate comprising a perimeter, in a process chamber, the substrate support comprising:
(a) an electrostatic chuck having a receiving surface to receive the substrate; and
(b) a gas distributor baseplate below the electrostatic chuck, the gas distributor baseplate comprising a circumferential sidewall having a plurality of gas outlets that are spaced apart from one another to introduce a process gas into the process chamber from around the perimeter of the substrate and in a radially outward facing direction.

2. A support according to claim 1 wherein the gas distributor baseplate comprises an axis of rotational symmetry and the gas outlets are spaced apart around the circumferential sidewall as measured from the axis of rotational symmetry by angles of from about 5° to about 45°.

3. A support according to claim 1 wherein the gas outlets are sized from about 1 mm to about 10 mm.

4. A support according to claim 1 wherein the gas distributor baseplate comprises an annular feed channel that supplies process gas to the gas outlets.

5. A support according to claim 4 wherein the process chamber comprises a gas feed port, and the annular feed channel comprises a gas connector to connect to the gas feed port.

6. A support according to claim 1 wherein the gas distributor baseplate comprises a right cylinder.

7. A support according to claim 6 wherein the right cylinder is composed of metal.

8. A support according to claim 7 wherein the process chamber comprises enclosure walls and a power supply, and wherein the gas distributor baseplate comprises an electrical connector to connect to a power supply or ground to maintain the baseplate at an electrical potential relative to the enclosure walls of the process chamber.

9. A support according to claim 1 comprising a dielectric pedestal between the electrostatic chuck and the gas distributor baseplate.

10. A support according to claim 9 wherein the dielectric pedestal comprises a polymer.

11. A substrate processing apparatus comprising the substrate support of claim 1 and further comprising:
(a) a process chamber to hold the substrate support;
(b) a plasma-generating system comprising a gas energizer to energize the process gas to form a plasma; and
(c) an exhaust to exhaust the process gas from the process chamber.

12. A method of depositing a material on a substrate in a process chamber, the substrate having a perimeter, and the method comprising:
(a) holding the substrate in the chamber;
(b) flowing process gas into the chamber
(i) from spaced apart points that are about, and outside, the perimeter of the substrate, and
(ii) in a radially outward facing direction; and
(c) energizing the process gas to deposit material onto the substrate.

13. A method according to claim 12 comprising introducing the process gas from points that are spaced apart around the perimeter of the substrate and separated by radial angles of from about 5° to about 45°.

14. A method according to claim 12 further comprising implanting ions into the substrate before or during deposition of the material on the substrate.

15. A process chamber capable of depositing material and implanting ions in a substrate, the substrate having a perimeter, and the process chamber comprising:
(a) a housing having enclosure walls;
(b) a substrate support for receiving a substrate in the housing, the substrate support comprising:
(i) an electrostatic chuck having a receiving surface to receive the substrate; and
(ii) a gas distributor baseplate below the electrostatic chuck, the gas distributor baseplate comprising a circumferential sidewall having a plurality of gas outlets that are spaced apart from one another to introduce a process gas into the housing from around the perimeter of the substrate and in a radially outward facing direction;
(c) a plasma-generating system to energize the process gas to form a plasma capable of depositing material on the substrate or implanting ions into the substrate; and
(d) an exhaust to exhaust the process gas from the process chamber.

16. A chamber according to claim 15 wherein the gas distributor baseplate comprises an axis of rotational symmetry, and the gas outlets are spaced apart around the circumferential sidewall as measured from the axis of rotational symmetry by angles of from about 5° to about 45°.

17. A chamber according to claim 15 wherein the gas outlets are sized from about 1 mm to about 10 mm.

18. A chamber according to claim 15 wherein the gas distributor baseplate comprises an annular feed channel that supplies process gas to the gas outlets.

19. A chamber according to claim 18 wherein the process chamber comprises a gas feed port, and the annular feed channel comprises a gas connector to connect to the gas feed port.

20. A chamber according to claim 15 wherein the gas distributor baseplate comprises a right cylinder of metal, and an electrical connector to connect to a power supply or ground.
